(19) United States
(12) Patent Application Publication
(10) Pub. No.: US 2015/0179408 A1
(43) Pub. Date: Jun. 25, 2015

(54) SUBSTRATE PROCESSING APPARATUS AND SUBSTRATE PROCESSING METHOD

(71) Applicant: Tokyo Electron Limited, Tokyo (JP)

(72) Inventors: Kouji Shimomura, Nirasaki City (JP); Naotaka Noro, Nirasaki City (JP); Eiichi Nishimura, Kurokawa-gun (JP)

(21) Appl. No.: 14/580,610

(22) Filed: Dec. 23, 2014

(30) Foreign Application Priority Data
Dec. 25, 2013 (JP) 2013-266834

(51) Int. Cl. H01J 37/32; H01L 21/02; H01L 21/3065; C23C 16/511; C23C 16/46

(52) U.S. Cl. CPC H01J 37/32192; C23C 16/511; C23C 16/46; H01J 37/32724; H01L 21/3065; H01L 21/02617; H01J 2237/332; H01J 2237/334

(57) ABSTRACT

A substrate processing apparatus and a substrate processing method can perform a plasma process using a microwave and a heat treatment through irradiation of the microwave on a substrate. A substrate processing apparatus 1 includes a processing vessel 2; a microwave introduction device 3 configured to introduce a microwave into the processing vessel 2; a mounting table 4 configured to support a wafer W thereon within the processing vessel 2. The mounting table 4 is made of a microwave-transmissive material. The processing vessel 2 has therein a plasma processing space S1 in which a plasma process is performed on the wafer W; and a microwave introduction space S2 into which the microwave is directly introduced. The microwave having transmitted the mounting table 4 is first used to heat the wafer W before it reaches the plasma processing space S1 to be consumed by plasma.

### CROSS-REFERENCE TO RELATED APPLICATION

This application claims the benefit of Japanese Patent Application No. 2013-266834 filed on Dec. 25, 2013, the entire disclosures of which are incorporated herein by reference.

### TECHNICAL FIELD

The embodiments described herein pertain generally to a substrate processing method and a substrate processing apparatus that performs a process on a substrate by introducing a microwave into a processing vessel.

### BACKGROUND

As a substrate processing apparatus that performs a process on a substrate such as a semiconductor wafer by using a microwave, there is known a substrate processing apparatus that generates plasma of a gas by a microwave and performs a plasma process such as a film forming process or an etching process on the substrate by the plasma.

As such a substrate processing apparatus using a microwave, there is also proposed a substrate processing apparatus configured to perform an annealing process by directly irradiating a microwave to a substrate (see, for example, Patent Documents 1 and 2). The annealing process by a microwave has an advantage in that an inside heating, a local heating, and a selective heating can be performed compared to the conventional lamp heating method or resistance heating method.

Patent Document 1: Japanese Patent Laid-open Publication No. 2007-258286 (e.g., FIG. 1)

Patent Document 2: Japanese Patent Laid-open Publication No. 2011-077065 (e.g., FIG. 1)

When performing a plasma process on a substrate by a microwave introduced into a processing vessel, the inside of the processing vessel needs to be decompressed to a vacuum, e.g., to a pressure of about 10 Pa to about 1000 Pa in order to generate stable plasma. Meanwhile, when performing an annealing process on a substrate, it may be desirable to perform the annealing process at a pressure near an atmospheric pressure in order to suppress an abnormal electric discharge from being generated or a gas from being excited into plasma by a microwave irradiated to the substrate. That is, a processing pressure in the plasma process and a processing pressure in the annealing process are greatly different, though the microwave is used in both processes. In this regard, a substrate processing apparatus capable of performing both the plasma process and the annealing process has yet to be put to practical use.

### SUMMARY

In view of the foregoing, example embodiments provide a substrate processing apparatus and a substrate processing method of performing both a plasma process using a microwave and a heat treatment through irradiation of the microwave on a substrate.

In one example embodiment, a substrate processing apparatus includes a processing vessel configured to accommodate a substrate therein; a supporting member which is made of a microwave-transmissive material that transmits a microwave and is configured to support the substrate within the processing vessel; a gas supply device configured to introduce a gas for plasma generation into the processing vessel; and a microwave introduction device, having a microwave source that generates the microwave, configured to introduce the microwave into the processing vessel. Further, by the microwave that transmits the supporting member, the substrate supported by the supporting member is heated and plasma is generated in the processing vessel to perform a plasma process on the substrate.

The plasma may be generated by the microwave that transmits the substrate after transmitting the supporting member and irradiating the substrate.

The processing vessel may include a first space configured to be evacuated to a vacuum level and perform therein the plasma process on the substrate and a second space which is connected to the microwave introduction device and into which the microwave is directly introduced, and the first space and the second space may be separated by the supporting member.

The processing vessel may include a ceiling portion, a bottom wall portion and a sidewall portion connecting the ceiling portion and the bottom wall portion. Here, a gas inlet unit connected to the gas supply device and configured to introduce the gas into the processing vessel may be provided at the ceiling portion, and a microwave inlet unit connected to the microwave introduction device and configured to introduce the microwave into the processing vessel may be provided at the bottom wall portion.

The supporting member may have a flow path through which a heat transfer medium for adjusting a temperature of the substrate is circulated. Here, the heat transfer medium may be a fluorine-based solvent.

The microwave-transmissive material may be quartz.

In another example embodiment, a substrate processing method is performed in a substrate processing apparatus including a substrate processing vessel configured to accommodate a substrate therein; a supporting member which is made of a microwave-transmissive material that transmits a microwave and is configured to support the substrate within the processing vessel; a gas supply device configured to introduce a gas for plasma generation into the processing vessel; and a microwave introduction device, having a microwave source that generates a microwave, configured to introduce the microwave into the processing vessel.

In this substrate processing method, by the microwave that transmits the supporting member, the substrate supported by the supporting member is heated and plasma is generated in the processing vessel to perform a plasma process on the substrate.

In yet another example embodiment, a substrate processing method includes heating the substrate, which is supported by the supporting member, by the microwave that transmits the supporting member; and generating plasma in the processing vessel and performing a plasma process on the substrate while concurrently heating the substrate, which is supported by the supporting member, by the microwave that transmits the supporting member.

According to the substrate processing apparatus and the substrate processing method of the example embodiments, both a plasma process using a microwave and a heat treatment through irradiation of the microwave can be performed on a substrate.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a cross sectional view illustrating a schematic configuration of a substrate processing apparatus in accordance with an example embodiment;

FIG. 2 is a diagram illustrating a schematic configuration of a microwave introduction device of the substrate processing apparatus shown in FIG. 1;

FIG. 3 is a diagram illustrating a schematic configuration of a high voltage power supply unit of the substrate processing apparatus shown in FIG. 1;

FIG. 4 is a plane view illustrating a top surface of a bottom wall portion of a processing vessel shown in FIG. 1;

FIG. 5 is a block diagram illustrating a configuration of a control unit;

FIG. 6 is a diagram schematically illustrating a state in which a plasma process and an annealing process with a microwave are performed at the same time in the substrate processing apparatus; and

FIG. 7 is diagram schematically illustrating a state in which only an annealing process with a microwave is performed in the substrate processing apparatus.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current example embodiment. Still, the example embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

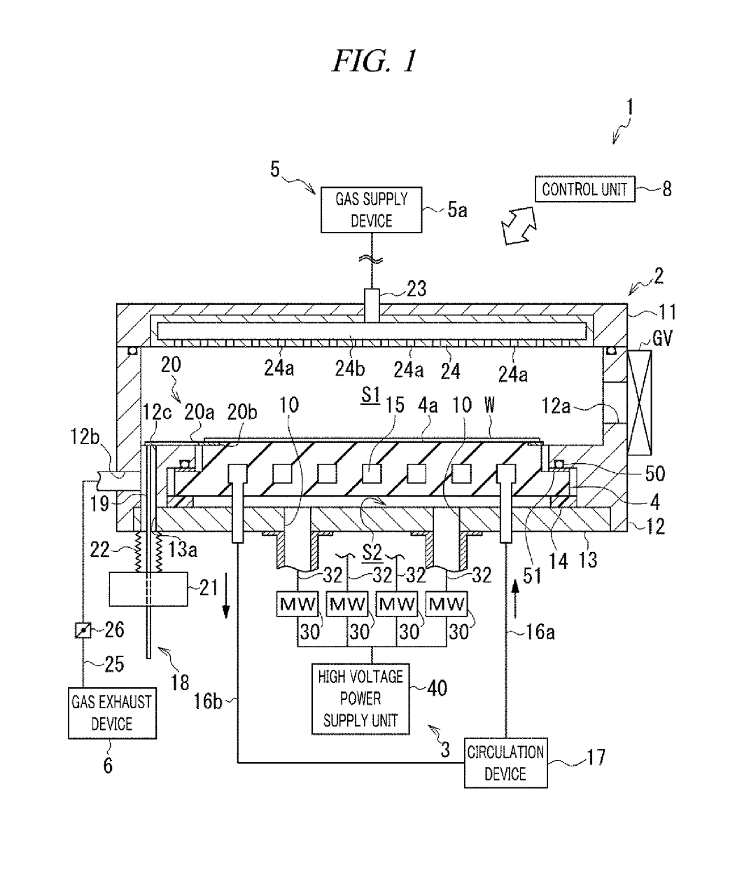

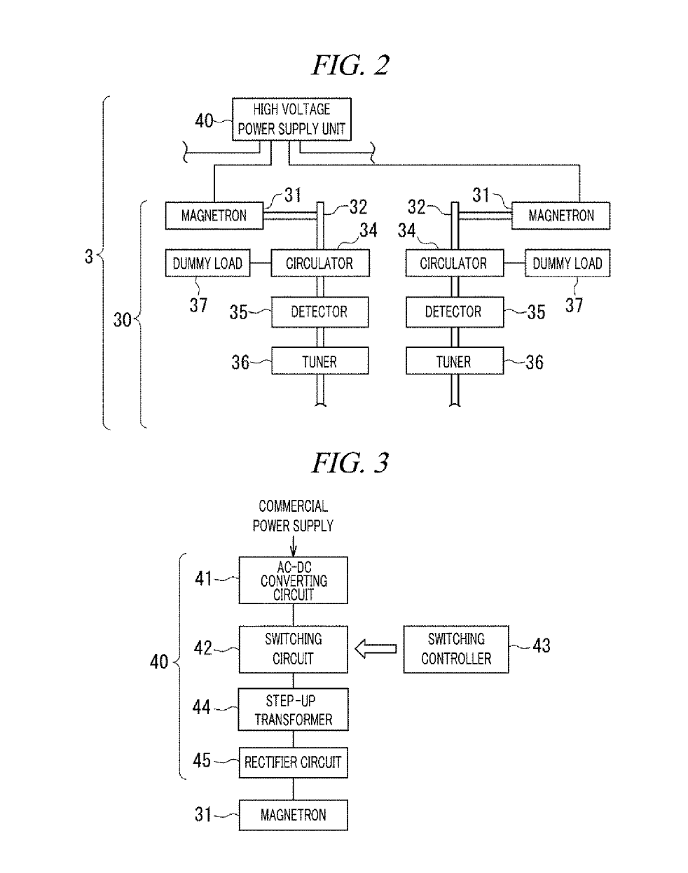

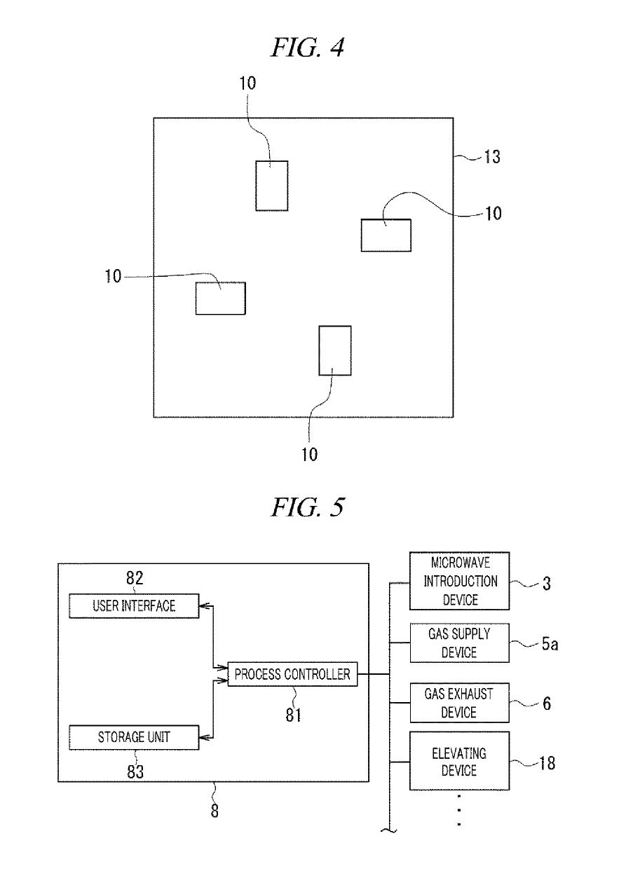

First, a substrate processing apparatus in accordance with an example embodiment will be elaborated with reference to FIG. 1. FIG. 1 is a cross sectional view illustrating a schematic configuration of a substrate processing apparatus 1, and FIG. 2 is a diagram illustrating a schematic configuration of a microwave introduction device 3 in the substrate processing apparatus 1. FIG. 3 is a diagram illustrating a schematic configuration of a high voltage power supply unit of the microwave introduction device 3, and FIG. 4 is a plane view illustrating a top surface of a bottom wall portion 13 of a processing vessel 2 shown in FIG. 1. The substrate processing apparatus 1 is configured to perform, through multiple consecutive operations, both a plasma process and an annealing process by irradiating a microwave on, e.g., a semiconductor wafer (hereinafter, simply referred to as a “wafer”) W used in manufacturing a semiconductor device. Here, in top and bottom surfaces of the flat plate wafer W having large areas, the top surface is a semiconductor device forming surface, i.e., a main surface as a processing target surface.

The substrate processing apparatus 1 includes the processing vessel 2 configured to accommodate the wafer W as a processing target object therein; the microwave introduction device 3 configured to introduce a microwave into the processing vessel 2; a mounting table 4 serving as a supporting member configured to support the wafer W thereon within the processing vessel 2; and a gas supply unit 5 configured to supply a gas into the processing vessel 2; a gas exhaust device 6 configured to evacuate the inside of the processing vessel 2; and a control unit 8 configured to control the individual components of the substrate processing apparatus 1.

<Processing Vessel>

The processing vessel 2 is made of a metal material such as, but not limited to, aluminum, an aluminum alloy, stainless steel, or the like. The processing vessel 2 has therein a plasma processing space S1 as a first space, in which a plasma process is performed on the wafer W, configured to be evacuated to a vacuum level; and a microwave introduction space S2 as a second space which is connected to the microwave introduction device 3 and into which the microwave is directly introduced.

The processing vessel 2 has a ceiling portion 11 as a top wall; a bottom wall portion 13 as a bottom wall; and four sidewall portions 12 as sidewalls connecting the ceiling portion 11 and the bottom wall portion 13. A loading/unloading opening 12a and a gas exhaust opening 12b are formed at the sidewall portions 12. The loading/unloading opening 12a is provided to perform loading/unloading of the wafer W into/from the processing vessel 2 with respect to a non-illustrated adjacent transfer chamber. A gate valve GV is provided between the processing vessel 2 and the non-illustrated transfer chamber. The gate valve GV serves to open and close the loading/unloading opening 12a. In a closed state, the gate valve GV hermetically seals the plasma processing space S1 of the processing vessel 2, whereas in an open state, the gate valve GV allows the wafer W to be transferred between the processing space S1 of the processing vessel 2 and the non-illustrated transfer chamber. Further, multiple microwave inlet ports 10 are provided to penetrate the bottom wall portion 13 vertically, and the microwave inlet ports 10 serve as a microwave inlet unit configured to introduce a microwave into the processing vessel 2. Each microwave inlet port 10 has a rectangular shape having long sides and short sides, when viewed from the top. The microwave inlet ports 10 may have different sizes or different ratios between the long sides and the short sides. From the viewpoint of improving uniformity of an annealing process and a plasma process upon the wafer W and improving controllability, however, it may be desirable that the multiple microwave inlet ports 10 have the same size and the same shape.

<Supporting Member>

The mounting table 4 as a supporting member configured to support the wafer W is provided on the bottom wall portion 13 of the processing vessel 2 with a spacer 14 therebetween. The mounting table 4 is made of a microwave-transmissive material which rarely absorbs a microwave and easily transmits the microwave. That is, the mounting table 4 is made of a material in which an amount of the temperature rise by dielectric heating is small. The microwave-transmissive material may be, by way of example, a dielectric material such as, but not limited to, quartz, ceramics such as alumina, or a synthetic resin. Among these dielectric materials, it may be most desirable to use quartz which has heat resistance and tends to easily transmit the microwave.

A temperature rise by the dielectric heating is proportional to the product of a relative permittivity and a dielectric-loss angle of a material. It is possible to suppress the mounting table 4 from being heated if a material having this product value smaller than 0.005, more desirably, 0.001 is used. In the present example embodiment, the mounting table 4 is made of, for example, quartz as a material having the product value smaller than 0.005. Thus, the mounting table 4 transmits most of microwaves radiated to the wafer W. As a result, the mounting table 4 can be suppressed from being heated itself, or the microwaves can be suppressed from being reflected from the mounting table 4 and deteriorating the uniformity of an electric field distribution in the vicinity of the wafer W. Further, the mounting table 4 needs to endure a temperature when the wafer W is heat-treated. The heating temperature for the wafer W may be in the range from, about 200° C. to about 850° C. depending on the purposes of the heat treatments. Thus, it may be desirable that the mounting table 4 is made of a material, such as quartz, having a heat resistant temperature equal to or higher than 900° C.

Examples of the material having the product value of the relative permittivity and the dielectric-loss angle thereof less than 0.005 may include, besides the quartz, polytetrafluoroethylene, polystyrene, and so forth. Since polytetrafluoroethylene and polystyrene have a heat resistance temperature of about 200° C., which is lower than that of the quartz, they may be desirably used as a material for the mounting table 4 when performing a heat treatment on the wafer W at a relatively low temperature up to about 200° C.

A mounting surface 4a on which the wafer W is mounted is formed on a top surface of the mounting table 4. The mounting surface 4a is a surface portion of the mounting table 4 that directly faces the plasma processing space S1. In the substrate processing apparatus 1 of the present example embodiment, the size (area) and the shape of the mounting surface 4a are set to be substantially the same as the size (area) and the shape of the wafer W. Accordingly, a microwave having transmitted the mounting table 4 can be irradiated to the entire wafer W from the entire mounting surface 4a. Further, the microwave transmitted the mounting table 4 can be radiated to the plasma processing space S1 above the wafer W from the entire wafer W. As a result, it is possible to allow a heating temperature in the entire surface of the wafer W to be uniform, and generate plasma in a uniform distribution within the plasma processing space S1 above the wafer W.

The spacer 14 is provided to form the microwave introduction space S2 between a top surface of the bottom wall portion 13 of the processing vessel 2 and a bottom surface of the mounting table 4. Desirably, a synthetic resin having heat resistance may be used as the spacer 14, and, more desirably, a synthetic resin film such as, but not limited to, polytetrafluoroethylene or polyimide may be used.

Further, though not shown, it is desirable to provide a clamp device configured to press the wafer W against the mounting surface 4a of the mounting table 4 in order to improve adhesivity between the wafer W and the mounting table 4. If a gap is formed between the rear surface of the wafer W and the mounting table 4, an abnormal electric discharge may be generated within the gap, or a temperature discrepancy may be generated in the surface of the wafer W since a phase of the microwave is changed depending on the presence or absence of the gap. By providing the clamping device, however, the wafer W can be brought into firm contact with the mounting table 4, so that it is possible to suppress the abnormal electric discharge or the temperature discrepancy within the surface of the wafer W from being generated. As the clamp device, a well-known clamp configuration may be utilized.

Provided within the mounting table 4 is a flow path 15 through which a heat transfer medium configured to control a temperature of the wafer W mounted on the mounting table 4 is circulated. The flow path 15 is connected to an inlet line 16a and an outlet line 16b which are formed through the bottom wall portion 13. The inlet line 16a and the outlet line 16b are connected to a circulation device 17. The circulation device 17 includes, though not shown, a pump configured to circulate the heat transfer medium, a heat exchanger configured to heat or cool the heat transfer medium, and so forth. The heat transfer medium adjusted to a preset temperature is introduced from the circulation device 17 into the flow path 15 of the mounting table 4 through the inlet line 16a and returned back into the circulation device 17 after discharged through the outlet line 16b. By circulating the heat transfer medium in this way, the wafer W mounted on the mounting table 4 can be cooled or heated.

The flow path 15 is formed by, for example, cutting off the inside of the mounting table 4. In this case, the mounting table 4 may be composed of plural members (e.g., quartz plates) adjoined to each other. However, the flow path 15 need not necessarily be formed by cutting-off, and the way to form the flow path 15 may be selected appropriately. As for the arrangement of the flow path 15, the flow path 15 may be formed to heat or cool the entire surface of the wafer W, effectively, for example, when viewed from the top, in a spiral shape or may be formed such that it is bent repeatedly within the mounting table 4, but not limited thereto.

A liquid without having electric polarity may be desirably used as the heat transfer medium. Since the liquid without having the electric polarity does not absorb a microwave, a temperature rise by the dielectric heating of the microwave can be suppressed. One example of the liquid without having an electric polarity may be, but not limited to, perfluoropolyether (PFPE) as a fluoroorganic-based liquid. By using the liquid without having the electric polarity as the heat transfer medium, the heat transfer medium may be suppressed from being affected by the microwave transmitting the mounting table 4. For example, even when cooling the wafer W by the heat transfer medium while allowing transmitting the microwave through the mounting table 4, the heat transfer medium without having the electric polarity within the flow path 15 is mostly not heated by the microwave. Thus, the heat exchange between the heat transfer medium and the mounting table 4 becomes dominant, so that the wafer W can be cooled efficiently and stably.

<Elevating Device>

An elevating device 18 includes a height displacement device configured to vary a height position of the wafer W while supporting the wafer W thereon. The elevating device 18 is used to mount the wafer W on the mounting table 4 or to transfer the wafer W between the mounting table 4 and a non-illustrated transfer device. The elevating device 18 includes a shaft 19 inserted through an opening 13a, which is provided through the bottom wall portion 13, and, also, through a through hole 12c of the sidewall portion 12; a supporting arm 20 connected to an upper end of the shaft 19; and an elevation driving unit 21 configured to move the supporting arm 20 up and down via the shaft 19. A lower portion of the shaft 19 is protruded out of the processing vessel 2 through the opening 13a. Further, the elevation driving unit 21 is provided outside the processing vessel 2. A vacuum maintaining member such as, e.g., bellows is disposed around the opening 13a. The vacuum maintaining member 22 is configured to maintain airtightness of the opening 13a, the through hole 12c and the plasma processing space S1, so that a vacuum state can be maintained.

The supporting arm 20 has a base member 20a and an annular member 20b horizontally extended from the base member 20a. The base member 20a is connected to the shaft 19. The annular member 20b has a shape conforming to the circular outline of the wafer W and is configured to support the wafer W by coming into contact with an edge portion of the rear surface of the wafer W. The supporting arm 20 is configured to be moved up and down along with the shaft 19 by the elevation driving unit 21. The supporting arm 20 is made of a dielectric material such as, but not limited to, quartz or ceramics such that a microwave can transmit the supporting arm 20. The elevation driving unit 21 may not be particularly limited as long as it is capable of moving the shaft 19 up and down. By way of example, the elevation driving unit 21 may be equipped with, e.g., non-illustrated ball screws, or the like. Further, the displacement device configured to vary the height position of the wafer W may have a configuration different from that of FIG. 1 as long as it is capable of varying the height position of the wafer W.

<Gas Introduction Unit>

The substrate processing apparatus 1 further includes a gas supply unit 5 configured to supply a gas into the processing vessel 2. The gas supply device 5 includes a gas supply device 5a equipped with a multiple number of non-illustrated gas supply sources; and a multiple number of pipelines 23 (only one of them is illustrated) for respectively introducing gases into the processing vessel 2. The multiple number of gas supply sources store therein different kinds of gases, and the multiple number of pipelines 23 are connected from the respective gas supply sources to the ceiling portion 11 of the processing vessel 2.

A shower head 24 as a gas inlet unit configured to introduce a gas into the processing vessel 2 is provided at the ceiling portion 11 of the processing vessel 2. The shower head 24 is disposed above the mounting table 4, facing the plasma processing space S1. A bottom surface of the shower head 24 faces the top surface (mounting surface 4a) of the mounting table 4 in parallel. A multiple number of gas discharge holes 24a are formed in the bottom surface of the shower head 24. Further, the shower head 24 has therein a gas diffusion space 24b that communicates with the pipelines 23 and diffuses the gases therein. One end of each pipeline 23 is connected to the gas supply device 5a, and the other end thereof is connected to the shower head 24. A gas introduced into the gas diffusion space 24b within the shower head 24 from each pipeline 23 is supplied into the plasma processing space S1 below the shower head 24 through the gas discharge holes 24a.

The gas supply device 5a is configured to select the appropriate gas kind such as, but not limited to, a film forming gas, an etching gas and a rare gas species for plasma generation depending on purposes of plasma processes and supply the selected gas kind into the processing vessel 2 via the pipeline 23 and the shower head 24. Though not shown, the substrate processing apparatus 1 is equipped with mass flow controllers and opening/closing valves provided at the pipelines 23. The kinds of the gases supplied into the processing vessel 2, flow rates of these gases, and so forth are controlled by the mass flow controllers and the opening/closing valves.

Further, an external gas supply device which is not included in the substrate processing apparatus 1 may be provided in lieu of the gas supply device 5a. In addition, the gas inlet unit configured to introduce the gases may be provided at a place other than the ceiling portion 11, for example, at the sidewall portion 12.

<Gas Exhaust Device>

The gas exhaust device 6 includes, for example, a vacuum pump such as a dry pump or a turbo molecular pump. The substrate processing apparatus 1 further includes a gas exhaust line 25 connecting the gas exhaust device 6 and the gas exhaust opening 12b formed in the sidewall portion 12; and a pressure control valve 26 provided at a certain portion of the gas exhaust line 25. The gas exhaust device 6 is connected to the plasma processing space S1 within the processing vessel 2 via the gas exhaust line 25 and the gas exhaust opening 12b. Accordingly, by operating the vacuum pump of the gas exhaust device 6, the plasma processing space S1 is depressurized and evacuated to a preset pressure level.

<Temperature Measurement Unit>

Though not shown, the substrate processing apparatus 1 further includes radiation thermometers configured to measure a surface temperature of the wafer W; and a temperature measurement unit connected to the radiation thermometers.

<Microwave Introduction Device>

Now, referring to FIG. 1 to FIG. 4, a configuration of the microwave introduction device 3 will be elaborated. As stated above, the microwave introduction device 3 is provided under the processing vessel 2 and serves as a microwave introduction unit configured to introduce an electromagnetic wave (microwave) into the processing vessel 2. As shown in FIG. 1, the microwave introduction device 3 includes multiple microwave units (MW) 30 and a high voltage power supply unit 40 connected to the multiple microwave units (MW) 30.

(Microwave Units)

In the present example embodiment, all of the multiple microwave units (MW) 30 have the same configuration. FIG. 2 illustrates a detailed configuration of two microwave units (MW) 30. Each microwave unit (MW) 30 includes a magnetron 31 configured to generate a microwave for processing a wafer W; and a waveguide 32 as a transmission path that transmits the microwave generated by the magnetron 31 to the processing vessel 2. The magnetron 31 corresponds to a microwave source in the present example embodiment. The microwave unit (MW) 30 also includes a circulator 34, a detector 35 and a tuner 36 provided at certain portions of the waveguide 32; and a dummy load 37 connected to the circulator 34. The circulator 34, the detector 35 and the tuner 36 are arranged in this sequence from a connection end between the waveguide 32 and the magnetron 31.

As depicted in FIG. 4, in the present example embodiment, the processing vessel 2 includes four microwave inlet ports 10 that are formed in the bottom wall portion 13 and equi-spaced along a circumferential direction thereof. In this example embodiment, the microwave units (MW) 30 are connected to the microwave inlet ports 10 in one-to-one correspondence. That is, the number of the microwave units (MW) 30 is four.

The magnetron 31 has an anode and a cathode (both are not shown) to which a high voltage supplied by the high voltage power supply unit 40 is applied. Further, the magnetron 31 is configured to oscillate microwaves of various different frequencies. As for a microwave generated by the magnetron 31, an optimum frequency for each target process performed on a processing target object may be selected from, for example, an ISM (Industry-Science-Medical) band. Desirably, the frequency of the microwave may be, by way of example, but not limitation, 915 MHz, 2.45 GHz, 5.8 GHz or 24 GHz. Among these frequencies, 5.8 GHz is most desirable.

The waveguide 32 has a tube shape with a rectangular cross section and is extended downward from a bottom surface of the bottom wall portion 13 of the processing vessel 2. An upper end of the waveguide 32 is connected to the microwave inlet port 10, and a lower end thereof is connected to the magnetron 31. The microwave generated by the magnetron 31 is introduced into the processing vessel 2 through the waveguide 32.

The circulator 34 and the dummy load 37 constitute an isolator configured to separate a reflection wave from the processing vessel 2. That is, the circulator 34 guides the reflection wave from the processing vessel 2 to the dummy load 37, and the dummy load 37 converts the reflection wave guided by the circulator 34 into heat.

The detector 35 is configured to detect the reflection wave from the processing vessel 2 in the waveguide 32. The detector 35 may be implemented by, but not limited to, an impedance monitor, specifically, a standing wave monitor configured to detect an electric field of a standing wave in the waveguide 32. The standing wave monitor may be composed of, for example, three pins protruding into an internal space of the waveguide 32. The reflection wave from the processing vessel 2 can be detected by detecting a position, a phase and an intensity of the electric field of the standing wave through the standing wave monitor. Alternatively, the detector 35 may be implemented by a directional coupler capable of detecting a progressive wave and a reflection wave.

The tuner 36 has a function of performing impedance matching (below, simply referred to as “matching”) between the magnetron 31 and the processing vessel 2. The matching by the tuner 36 is performed based on a detection result of the reflection wave by the detector 35. The tuner 36 may be implemented by, for example, a conductive plate (not shown) configured to be protruded into or taken out of the internal space of the waveguide 32. In this configuration, by controlling a protruding amount of the conductive plate into the internal space of the waveguide 32, electric energy of the reflection wave can be adjusted, so that an impedance between the magnetron 31 and the processing vessel 2 can be adjusted.

(High Voltage Power Supply Unit)

The high voltage power supply unit 40 is configured to supply a high voltage for generating a microwave to the magnetron 31. As depicted in FIG. 3, the high voltage power supply unit 40 includes an AC-DC converting circuit 41 connected to a commercial power supply; a switching circuit 42 connected to the AC-DC converting circuit 41; a switching controller 43 configured to control an operation of the switching circuit 42; a step-up transformer 44 connected to the switching circuit 42; and a rectifier circuit 45 connected to the step-up transformer 44. The magnetron 31 is connected to the step-up transformer 44 via the rectifying circuit 45.

The AC-DC converting circuit 41 is a circuit configured to rectify an AC (e.g., a three-phase AC of 200 V) from the commercial power supply to convert the AC into a DC having a certain waveform. The switching circuit 42 is a circuit configured to control on/off operations of the DC converted by the AC-DC converting circuit 41. In the switching circuit 42, a phase-shift type PWM (Pulse Width Modulation) control or a PAM (Pulse Amplitude Modulation) control is performed under the control of the switching controller 43, so that a pulse type voltage waveform is generated. The step-up transformer 44 is configured to step-up the voltage waveform outputted from the switching circuit 42 to voltage waveform having a preset magnitude. The rectifier circuit 45 is a circuit configured to rectify the voltage stepped-up by the step-up transformer 44 and supply the rectified voltage to the magnetron 31.

<Plasma Processing Space and Microwave Introduction Space>

As stated above, in the substrate processing apparatus 1 in accordance with the present example embodiment, a space partitioned by the ceiling portion 11, the four sidewall portions 12 and the mounting table 4 within the processing vessel 2 is configured as the plasma processing space S1. The plasma processing space S1 is connected with the gas supply units, and a plasma processing gas is introduced into the plasma processing space S1. Further, the plasma processing space S1 is also connected with the gas exhaust device 6 and can be evacuated to a preset pressure. Meanwhile, in the substrate processing apparatus 1 in accordance with the present example embodiment, a space partitioned by the bottom wall portion 13, the four sidewall portions 12 and the mounting table 4 is configured as the microwave introduction space S2. This microwave introduction space S2 is connected with the microwave introduction device 3 via the multiple microwave inlet ports 10. Microwaves are introduced into the microwave introduction space S2 from the individual microwave inlet ports 10.

The mounting table 4 positioned between the plasma processing space S1 and the microwave introduction space S2 isolates the two spaces. That is, the mounting table 4 serves as a partition wall that separates the plasma processing space S1 and the microwave introduction space S2. An O-ring 50 as a seal member is provided between the mounting table 4 and the sidewall portions 12. The O-ring 50 secures airtightness between the microwave introduction space S2 under the atmospheric atmosphere and the plasma processing space S1 evacuated to a vacuum level when generating plasma. Further, in order to avoid a direct contact between the mounting table 4 and the sidewall portions 12, a resin sheet 51 is also provided at the region where the O-ring 50 is provided. Desirably, a synthetic resin having heat resistance may be used as the resin sheet 51, and, more desirably, a synthetic resin film such as, but not limited to, polytetrafluoroethylene or polyimide may be used as the resin sheet 51. In order to avoid a direct contact between side portions of the mounting table 4 and the sidewall portions 12, it may be desirable to form a gap between the side portions of the mounting table 4 and the sidewall portions 12 except for the region where the O-ring 50 is provided. By providing such a gap, an electric discharge (plasma generation) at the boundary between the side portions of the mounting table 4 and the sidewall portions 12 can be suppressed.

In a general plasma processing apparatus, when plasma is being generated in a processing vessel, a microwave introduced into the processing vessel may not be used to heat a wafer W because most of the microwave is consumed by the plasma. In the substrate processing apparatus 1 of the present example embodiment, however, a microwave having transmitted the mounting table 4 after introduced into the microwave introduction space S2 within the processing vessel 2 can be first irradiated to the wafer W. That is, in the substrate processing apparatus 1, the mounting table 4 serving as a partition wall between the plasma processing space S1 and the microwave introduction space S2 while supporting the wafer W thereon is used as a microwave transmitting window as well. Accordingly, the microwave having transmitted the microwave transmitting window (mounting table 4) is first used to heat the wafer W before it reaches the plasma processing space S1, and then, is consumed by plasma. In the plasma processing space S1, plasma is generated by the microwave having transmitted the wafer W, and a plasma process can be performed on the wafer W by using the plasma.

In the substrate processing apparatus 1 in accordance with the present example embodiment, the area of the top surface of the mounting table 4 facing the plasma processing space S1 may be set to be significantly larger than the area of the wafer W, e.g., 1.5 times to 3 times as large as the area of the wafer W. In such a configuration, in a region of the mounting table 4 where the wafer W is not placed, the microwave that has transmitted the mounting table 4 is directly irradiated to the microwave processing space S1. Accordingly, by allowing a certain percentage of the microwave that has transmitted the mounting table 4 to directly reach the plasma processing space S1 without being irradiated to the wafer W, it is possible to supply a greater amount of microwave into the plasma processing space S1. That is, in this method, the ratio of the microwave that reaches the plasma processing space S1 can be increased even with a same microwave output. Thus, this method has advantages when applied to a plasma process in which a large amount of microwave needs to be supplied to generate plasma in the substrate processing apparatus 1.

<Control Unit>

Individual components of the substrate processing apparatus 1 are connected to and controlled by the control unit 8. Typically, the control unit 8 is a computer. FIG. 5 is a diagram illustrating a configuration of the control unit 8 as depicted in FIG. 1. In the example shown in FIG. 5, the control unit 8 includes a process controller 81 having a CPU; a user interface 82 connected to the process controller 81; and a storage unit 83.

The process controller 81 is a control device configured to control individual components (for example, the microwave introduction device 3, the gas supply device 5a, the gas exhaust device 6, the elevating device 18, etc.) relevant to process conditions such as a pressure, a gas flow rate, a microwave output, and so forth.

The user interface 82 includes a keyboard and a touch panel through which a process manger inputs commands to manage the substrate processing apparatus 1; a display that visually displays an operational status of the substrate processing apparatus 1; and so forth.

The storage unit 83 stores therein control programs (software) for implementing various processes performed in the substrate processing apparatus 1 under the control of the process controller 81; or recipes including process condition data, and so forth. In response to an instruction from the user interface 82, a necessary control program or recipe is retrieved from the storage unit 83 and executed by the process controller 81. As a result, a required process is performed in the processing vessel 2 of the substrate processing apparatus 1 under the control of the process controller 81.

The control programs and the recipes may be used while being stored in a computer-readable storage medium such as a CD-ROM, a hard disk, a flexible disk, a flash memory or a DVD, or may be used on-line by being received from another apparatus through, for example, a dedicated line, whenever necessary.

In the substrate processing apparatus 1 having the above-described configuration, both a heat treatment using irradiation of a microwave and a plasma process using plasma generated by the microwave can be performed on a wafer W. Specifically, an annealing process and a plasma process can be performed on a wafer W in the substrate processing apparatus 1 at the same time.

[Process Sequence]

Now, there will be explained a process sequence when performing an annealing process and a plasma process concurrently on a wafer W in the substrate processing apparatus 1. First, an instruction is inputted from, for example, the user interface 82 to the process controller 81 in order to perform an annealing process and a plasma process at the same time. Subsequently, in response to the instruction, the process controller 81 reads out a recipe stored in the storage unit 83 or the computer-readable storage medium. Then, control signals are sent from the process controller 81 to individual end devices (for example, the microwave introduction device 3, the gas supply device 5a, the gas exhaust device 6, the elevating device 18, etc.) of the substrate processing apparatus 1.

Thereafter, the gate valve GV is opened, and a wafer W is loaded into the processing vessel 2 through the loading/unloading opening 12a and transferred onto the supporting arm 20 by the non-illustrated transfer device. Then, by moving the supporting arm 20 downward from a transfer position, the wafer W is mounted on the mounting table 4. Then, the gate valve GV is closed, and the plasma processing space S1 within the processing vessel 2 is evacuated by the gas exhaust device 6. The microwave introduction space S2 is set in an atmospheric pressure state or set at a pressure near the atmospheric pressure where an electric discharge may not occur easily. For example, the microwave introduction space S2 is maintained in a pressure range from, e.g., 70 kPa to 100 kPa. Then, a gas of a preset flow rate is introduced into the plasma processing space S1 within the processing vessel 2 from the shower head 24. The plasma processing space S1 is adjusted to a preset pressure ranging from, e.g., 10 Pa to 1000 Pa by adjusting a gas exhaust rate and a gas supply rate.

Subsequently, a voltage is applied to the magnetron 31 from the high voltage power supply unit 40, and microwaves are generated. The microwaves generated by the magnetron 31 propagate through the waveguide 32 and the microwave inlet ports 10 formed in the bottom wall portion 13, and then, are introduced into the microwave introduction space S2 within the processing vessel 2. In the present example embodiment, the microwaves are generated by multiple magnetrons 31 in sequence and introduced into the microwave introduction space S2 through the respective microwave inlet ports 10 alternately. Further, the multiple microwaves may be generated by the multiple magnetrons 31 at the same time, and the microwaves may be introduced into the microwave introduction space S2 from the respective microwave inlet ports 10 at the same time.

The microwaves introduced into the microwave introduction space S2 transmit the mounting table 4 made of a microwave-transmissive material such as quartz and are irradiated to a rear surface of the wafer W, so that the wafer W is rapidly heated by electromagnetic wave heating such as Joul heating, magnetic heating or induction heating. As a result, an annealing process is performed on the wafer W. By allowing a heat transfer medium such as a coolant to flow through the flow path 15 during the annealing process, a temperature control of the wafer W such as local cooling thereof can be implemented. Thus, a heating temperature in the surface of the wafer W can be uniformed.

Further, most of the microwaves that have transmitted the mounting table 4 also transmit the wafer W and reach the plasma processing space S1. Accordingly, the gas introduced from the shower head 24 is excited into plasma by the microwaves that have reached the plasma processing space S1. A preset plasma process is performed on a top surface (i.e., main surface) of the wafer W by this plasma.

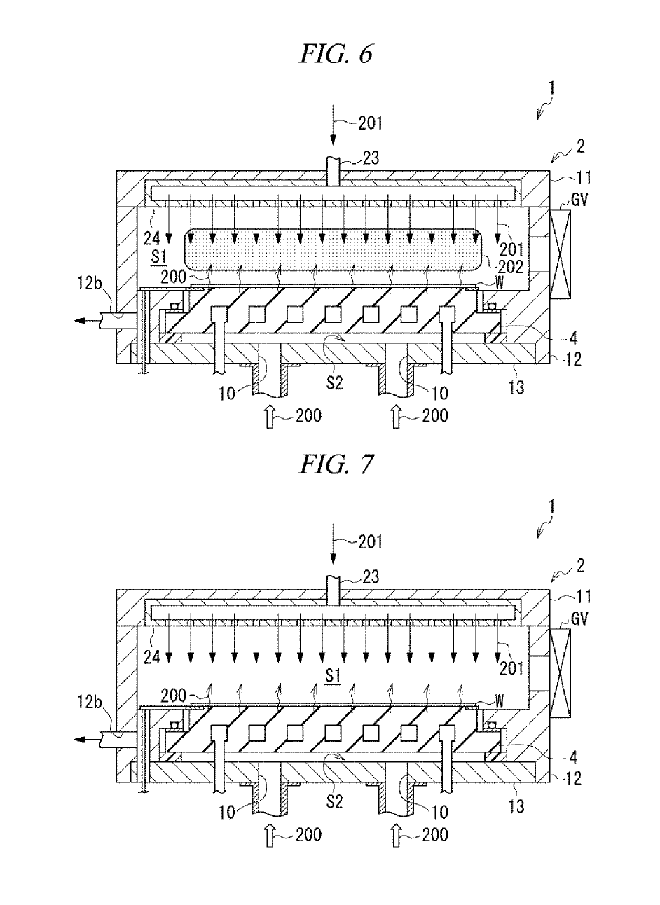

FIG. 6 schematically illustrates a state in which an annealing process and a plasma process are performed on a wafer W at the same time in the substrate processing apparatus 1. In this case, microwaves 200 introduced into the microwave introduction space S2 by the microwave introduction device 3 are irradiated to the wafer W after transmitting the mounting table 4. Most of the microwaves 200 irradiated to the wafer W also transmit the wafer W to be radiated to the plasma processing space S1. A gas 201 from the gas supply unit 5 is introduced into the plasma processing space S1 through the shower head 24. Since conditions for plasma generation such as pressure are set, plasma 202 is generated in the plasma processing space S1, and a plasma process is performed on the wafer W by the generated plasma 202. As stated above, in the substrate processing method in accordance with the example embodiment, the plasma process and the annealing process by the microwave irradiation can be performed on the wafer W at the same time.

Here, in the microwaves 200 having transmitted the mounting table 4, a ratio consumed for heating the wafer W may be in the range from about 10% to about 20% or thereabout, though the ratio may be differed depending on process conditions. Accordingly, about 80% to about 90% of the microwaves 200 having transmitted the mounting table 4 would be radiated to the plasma processing space S1 after transmitting the wafer W to be used in the plasma process by being consumed for generating the plasma 202. Further, a part of the microwaves 200 having transmitted the mounting table 4 may be absorbed by a wall surface of the processing vessel 2 or the like.

If control signals for stopping the annealing process and the plasma process are sent from the process controller 81 to the individual end devices of the substrate processing apparatus 1, generation of the microwaves is stopped, and the supplies of the gas and the heat transfer medium are stopped, so that the plasma process on the wafer W is ended. Then, after the pressure within the plasma processing space S1 is adjusted, the gate valve GV is opened. The supporting arm 20 supporting the wafer W thereon is moved upward to the transfer position, and the wafer W is transferred onto the non-illustrated transfer device and unloaded from the processing vessel 2.

The substrate processing apparatus 1 can be widely employed in a plasma process accompanying heating of a wafer W in a manufacturing process for a semiconductor device, for example. Here, the plasma process may not be particularly limited. For example, the plasma process may be a plasma film forming process such as plasma CVD, a plasma diffusion process such as plasma oxidation or plasma nitrification, a plasma etching process, a plasma modification process, a plasma ashing process, a plasma pretreatment process such as a removal of substrate impurities, or the like. That is, the plasma processing apparatus 1 can be applied to various purposes.

In accordance with the substrate processing apparatus 1 in accordance with the present example embodiment, since the microwaves introduced into the processing vessel 2 can be used for the heat treatment and the plasma process of the wafer W, the efficiency of using the microwaves is high. Further, by using the microwaves, only the wafer W can be heated intensively, as compared to the conventional lamp heating method or resistance heating method. That is, the substrate processing apparatus 1 in accordance with the example embodiment has a very high energy using efficiency. Further, since the heat treatment on the wafer W and the plasma process on the wafer W can be performed at the same time by using only the microwaves, an additional heating equipment is not required, so that the apparatus can be simplified.

Furthermore, in the state in which the microwaves are introduced in the substrate processing apparatus 1 from the microwave introduction device 3, by selecting conditions, only the annealing process by the microwaves can be performed on the wafer W without generating plasma in the plasma processing space S1. Specifically, it is possible to create a state in which plasma is not generated in the plasma processing space S1 by selecting conditions as follows, for example:

(1) an internal pressure of the plasma processing space S1 is set to a high pressure (e.g., an atmospheric pressure) higher than 1000 Pa where it is difficult to generate plasma;

(2) a gas including a plasma generation gas capable of easily generating plasma is not introduced into the plasma processing space S1; and
(3) only a gas, such as a nitrogen gas, with which plasma is difficult to generate is introduced into the plasma processing space S1. Further, in the condition (2), the plasma generation gas may be, but not limited to, a rare gas such as He, Ne or Ar.

FIG. 7 schematically illustrates a state in which only an annealing process by the microwaves is performed on the wafer W in the substrate processing apparatus 1 according to one of the conditions (1) to (3). In this case, although the microwaves 200 introduced into the microwave introduction space S2 by the microwave introduction device 3 are irradiated to the wafer W after transmitting the mounting table 4 and then are radiated into the plasma processing space S1 after transmitting the wafer W, plasma is not generated in the plasma processing space S1. Further, the microwaves 200 having transmitted the wafer W are reflected in the plasma processing space S1, and used for the annealing process of the wafer W again. Accordingly, in FIG. 7, only the annealing process by the irradiation of the microwaves 200 can be performed on the wafer W.

Meanwhile, from the state of FIG. 7, the gas 201 is introduced into the plasma processing space S1 at a preset flow rate from the gas supply unit 5 via the shower head 24. By setting plasma generation conditions including the pressure, plasma 202 can be generated in the plasma processing space S1, as depicted in FIG. 6. Thus, in the state shown in FIG. 6, the plasma process and the annealing process by irradiation of the microwaves can be performed on the wafer W at the same time.

As stated above, in the substrate processing apparatus 1, it is possible to selectively implement either a state in which only the annealing process by the microwaves 200 is performed on the wafer W under the state where the plasma 202 is not generated in the plasma processing space S1 or a state in which both the annealing process and the plasma process are performed on the wafer W under the state where the plasma 202 is generated in the plasma processing space S1. That is, the present substrate processing method may include:

(i) an embodiment in which only the annealing process by the microwaves 200 is performed on the wafer W,

(ii) an embodiment in which both the annealing process and the plasma process are performed on the wafer W at the same time, or

(iii) an embodiment in which the embodiment (i) and the embodiment (ii) are switched.

As a specific example of the embodiment (iii), there may be performed, in the substrate processing apparatus 1, a process sequence including a first process of heating the wafer W by the microwaves 200 having transmitted the mounting table 4 and a second process of performing the plasma process on the wafer W by generating the plasma 202 in the plasma processing space S1 while concurrently heating the wafer W by the microwaves 200 having transmitted the mounting table 4. In this case, for example, the first process may be performed at a high pressure over 1000 Pa where the plasma 202 is difficult to generate, whereas the second process may be performed at a low pressure equal to or less than 1000 Pa where the plasma 202 tends to be easily generated. Further, in the embodiment (iii), the order of the embodiment (i) and the embodiment (ii), i.e., whether to perform the embodiment (i) or the embodiment (ii) first, or the switching number between the embodiment (i) and the embodiment (ii) may be selected as required. Further, it depends on the purposes of the process on the wafer W which one of the embodiments (i) to (iii) would be performed.

The above-described example embodiment is not limiting and can be modified in various ways. For example, the substrate processing apparatus of the example embodiment is not limited to an apparatus that handles a semiconductor wafer as a substrate. For example, an apparatus that processes a substrate for a solar cell panel or a substrate for a flat panel display as a substrate may also be applicable.

Further, the number of the microwave units 30 (the number of the magnetrons 31) or the number of the microwave inlet ports 10 in the substrate processing apparatus may not be limited the examples described in the example embodiment.

Moreover, in the substrate processing apparatus 1 of the example embodiment, an antenna configured to transmit a microwave may be provided at a region in the vicinity of the microwave inlet space S2.

In addition, in the substrate processing apparatus 1 in accordance with the example embodiment, with the mounting table 4 as a partition wall, the plasma processing space S1 is formed in the upper portion of the processing vessel 2 and the microwave introduction space S2 is formed in the lower portion of the processing vessel 2. Reversely, however, the plasma processing space S1 may be formed in the lower portion of the processing vessel 2 and the microwave introduction space S2 may be formed in the upper portion of the processing vessel 2. In such a configuration, the microwave transmitting window may be provided instead of the mounting table 4, and a wafer W with a top surface facing downward may be placed closely adhering to the microwave transmitting window by a supporting member. In this way, the same process as performed in the substrate processing apparatus 1 shown in FIG. 1 can be implemented.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

We claim:

1. A substrate processing apparatus, comprising:
a processing vessel configured to accommodate a substrate therein;
a supporting member which is made of a microwave-transmissive material that transmits a microwave and is configured to support the substrate within the processing vessel;
a gas supply device configured to introduce a gas for plasma generation into the processing vessel; and
a microwave introduction device, having a microwave source that generates the microwave, configured to introduce the microwave into the processing vessel,
wherein, by the microwave that transmits the supporting member, the substrate supported by the supporting member is heated and plasma is generated in the processing vessel to perform a plasma process on the substrate.

2. The substrate processing apparatus of claim 1,
wherein the plasma is generated by the microwave that transmits the substrate after transmitting the supporting member and irradiating the substrate.

3. The substrate processing apparatus of claim 1,
wherein the processing vessel comprises a first space configured to be evacuated to a vacuum level and perform therein the plasma process on the substrate and a second space which is connected to the microwave introduction device and into which the microwave is directly introduced, and
the first space and the second space are separated by the supporting member.

4. The substrate processing apparatus of claim 1,
wherein the processing vessel comprises a ceiling portion, a bottom wall portion and a sidewall portion connecting the ceiling portion and the bottom wall portion,
a gas inlet unit connected to the gas supply device and configured to introduce the gas into the processing vessel is provided at the ceiling portion, and
a microwave inlet unit connected to the microwave introduction device and configured to introduce the microwave into the processing vessel is provided at the bottom wall portion.

5. The substrate processing apparatus of claim 1,
wherein the supporting member has a flow path through which a heat transfer medium for adjusting a temperature of the substrate is circulated.

6. The substrate processing apparatus of claim 5,
wherein the heat transfer medium is a fluorine-based solvent.

7. The substrate processing apparatus of claim 1,
wherein the microwave-transmissive material is quartz.

8. A substrate processing method performed in a substrate processing apparatus including a substrate processing vessel configured to accommodate a substrate therein; a supporting member which is made of a microwave-transmissive material that transmits a microwave and is configured to support the substrate within the processing vessel; a gas supply device configured to introduce a gas for plasma generation into the processing vessel; and a microwave introduction device, having a microwave source that generates a microwave, configured to introduce the microwave into the processing vessel,
wherein, by the microwave that transmits the supporting member, the substrate supported by the supporting member is heated and plasma is generated in the processing vessel to perform a plasma process on the substrate.

9. A substrate processing method performed in a substrate processing apparatus including a substrate processing vessel configured to accommodate a substrate therein; a supporting member which is made of a microwave-transmissive material that transmits a microwave and is configured support the substrate within the processing vessel; a gas supply device configured to introduce a gas for plasma generation into the processing vessel; and a microwave introduction device, having a microwave source that generates a microwave, configured to introduce the microwave into the processing vessel, the substrate processing method comprising:
heating the substrate, which is supported by the supporting member, by the microwave that transmits the supporting member; and
generating plasma in the processing vessel and performing a plasma process on the substrate while concurrently heating the substrate, which is supported by the supporting member, by the microwave that transmits the supporting member.
